(19) United States
(12) Patent Application Publication
(10) Pub. No.: US 2013/0075783 A1
(43) Pub. Date: Mar. 28, 2013

(54) SEMICONDUCTOR DEVICE AND METHOD FOR MANUFACTURING THE SAME

(71) Applicants: Shinya YAMAZAKI, iOkazaki-shi (JP); Satoru KAMEYAMA, Toyota-shi (JP); Hitoshi SAKANE, Saijo-shi (JP); Jyoji ITO, Saijo-shi (JP)

(72) Inventors: Shinya YAMAZAKI, iOkazaki-shi (JP); Satoru KAMEYAMA, Toyota-shi (JP); Hitoshi SAKANE, Saijo-shi (JP); Jyoji ITO, Saijo-shi (JP)

(73) Assignee: TOYOTA JIDOSHA KABUSHIKI KAISHA, Toyota-shi (JP)

(21) Appl. No.: 13/618,220

(22) Filed: Sep. 14, 2012

(30) Foreign Application Priority Data
Sep. 28, 2011 (JP) 2011-213006

(51) Int. Cl. H01L 21/265; H01L 29/739

(52) U.S. Cl. 257/139; 438/530; 257/E29.198; 257/E21.334

(57) ABSTRACT

A semiconductor device includes: a semiconductor substrate, the semiconductor substrate comprising; an n type drift layer, a p type body layer on an upper surface side of the drift layer, and a high impurity n layer on a lower surface side of the drift layer. The high impurity n layer includes hydrogen ion donors as a dopant, and has a higher density of n type impurities than the drift layer. A lifetime control region including crystal defects as a lifetime killer is formed in the high impurity n layer and a part of the drift layer. A donor peak position is adjacent or identical to a defect peak position, at which a crystal defect density is highest in the lifetime control region in the depth direction of the semiconductor substrate. The crystal defect density in the defect peak position of the lifetime control region is 1×10¹² atoms/cm³ or more.

### CROSS-REFERENCE TO RELATED APPLICATION

This application claims priority to Japanese Patent Application No. 2011-213006 filed on Sep. 28, 2011, the contents of which are hereby incorporated by reference into the present application.

### TECHNICAL FIELD

The present teachings relate to a semiconductor device and a method of manufacturing the same.

### DESCRIPTION OF RELATED ART

In semiconductor devices, a region (in the present specification, hereinafter referred to as a lifetime control region) having a locally formed crystal defect is sometimes formed on a semiconductor substrate in order to control a lifetime of a carrier. For example, Japanese Patent Application Publication No. H9-121052 discloses a technique for forming a lifetime control region in a drift layer or a collector layer of an insulated gate-type bipolar transistor (IGBT) in order to reduce both a turn-off time and a turn-off loss of the IGBT. The lifetime control region is formed by implanting light ions such as hydrogen ions or helium ions into the drift layer or the collector layer of the IGBT.

In the IGBT, a buffer layer is sometimes formed between the drift layer and the collector layer. The buffer layer is generally formed by implanting impurity ions into the drift layer. For example, in a case of an n type drift layer and an n type buffer layer, the buffer layer is formed by implanting phosphorus ions, arsenic ions, or the like. In Japanese Patent Application Publication No. H9-121052, a lifetime control region is formed by irradiating light ions such as hydrogen ions or helium ions into a drift layer of an IGBT of a semiconductor substrate after forming the drift layer and a buffer layer on the semiconductor substrate.

In addition, Japanese Patent Application Publication No. 2001-160559 describes a method of forming a buffer layer by irradiating hydrogen ions to an n type drift layer at an acceleration energy of 1 MeV or less and then performing annealing at a low temperature. In Japanese Patent Application Publication No. 2001-160559, since the acceleration energy of the hydrogen ions is set low, a lifetime control region cannot be formed even if a buffer layer can be formed.

As in the case of Japanese Patent Application Publication No. H9-121052, manufacturing a high density n layer such as the buffer layer and forming the lifetime control region have conventionally been performed as separate processes. In Japanese Patent Application Publication No. 2001-160559, the hydrogen ions are irradiated in order to manufacture the buffer layer. However, it is neither expressed nor implied that the lifetime control region is formed by utilizing the irradiation of the hydrogen ions for manufacturing the buffer layer. As in the case of Japanese Patent Application Publication No. 2001-160559, when the hydrogen ions are irradiated at the acceleration energy of 1 MeV or less, even if the crystal defects remain, a density of the crystal defects is low. Therefore, the crystal defects cannot sufficiently function as a lifetime killer and are unable to contribute to improving characteristics of a semiconductor device.

### SUMMARY

The present inventors have discovered that a contribution can be made toward improving switching characteristics of a semiconductor device when a density of crystal defects at a crystal defect peak position in a lifetime control region is 1×10¹² atoms/cm³ or more. The present inventors have also discovered that by irradiating hydrogen ions to the semiconductor substrate at an acceleration energy of 2 MeV or more and subsequently converting the hydrogen ions into donors, the lifetime control region in which the density of crystal defects at the defect peak position is 1×10¹² atoms/cm³ or more is formed in the semiconductor substrate.

In one aspect of the present teachings, a semiconductor device may comprise an n type drift layer, a p type body layer on an upper surface side of the drift layer, and a high impurity n layer on a lower surface side of the drift layer, the high impurity n layer including hydrogen ion donors as a dopant, and having a higher density of n type impurities than the drift layer. A lifetime control region including crystal defects as a lifetime killer is formed in the high impurity n layer and a part of the drift layer. A donor peak position, at which a hydrogen ion donor density is highest in the high impurity n layer in a depth direction of the semiconductor substrate, is identical to a defect peak position, at which a crystal defect density is highest in the lifetime control region in the depth direction of the semiconductor substrate. The crystal defect density in the defect peak position of the lifetime control region is 1×10¹² atoms/cm³ or more.

In the semiconductor device described above, the crystal defects in the lifetime control region are formed by the hydrogen ions irradiated when forming the high impurity n layer. Therefore, the donor peak position, at which the hydrogen ion donor density is the highest in the high impurity n layer in the depth direction of the semiconductor substrate, is adjacent or identical to the defect peak position, at which the crystal defect density is the highest in the lifetime control region in the depth direction of the semiconductor substrate. In addition, the crystal defect density in the defect peak position of the lifetime control region is 1×10¹² atoms/cm³ or more, and has the crystal defect density distribution that enables the characteristics of the semiconductor device to be improved. According to the semiconductor device described above, the lifetime control region that is effective in improving the characteristics of the semiconductor device can be formed by utilizing the process of manufacturing the high impurity n layer.

### BRIEF DESCRIPTION OF DRAWINGS

FIG. 1 is a cross-sectional view of a semiconductor device according to a first embodiment.

FIG. 2 is a diagram illustrating a relationship between a crystal defect formation rate and an acceleration energy at which hydrogen ions are irradiated.

FIG. 3 is a diagram illustrating a relationship between a conversion rate of the hydrogen ions into donors and defect density/hydrogen ion density.

FIG. 4 is a diagram illustrating a relationship between switching loss and the acceleration energy at which the hydrogen ions are irradiated.

FIG. 5 is a diagram illustrating a relationship between a full width at half maximum of a density distribution of hydrogen ion donors and the acceleration energy at which the hydrogen ions are irradiated.

FIG. 6 is a diagram illustrating a diode used in a simulation.

FIG. 7 is an energy level diagram of the diode shown in FIG. 6.

FIG. 8 is a diagram illustrating a simulation result.

FIG. 9 is a diagram illustrating a simulation result.

FIG. 10 is a diagram illustrating a method for manufacturing the semiconductor device according to the first embodiment.

FIG. 11 is a diagram illustrating the method for manufacturing the semiconductor device according to the first embodiment.

FIG. 12 is a diagram illustrating the method for manufacturing the semiconductor device according to the first embodiment.

FIG. 13 is a diagram illustrating a distribution in a depth direction of a semiconductor substrate of an amount of crystal defects formed by the hydrogen ions irradiated in irradiating.

FIG. 14 is a diagram illustrating a crystal defect density distribution and a hydrogen ion donor density distribution of the semiconductor device according to the first embodiment.

FIG. 15 is a diagram illustrating current values and voltage values during turn-off of a semiconductor device according to the first embodiment and a semiconductor device according to a conventional example.

FIG. 16 is a diagram illustrating the hydrogen ion donor density distribution and an electric field intensity upon turnoff of the semiconductor device according to the first embodiment.

FIG. 17 is a diagram illustrating a carrier density distribution and a carrier lifetime distribution of the semiconductor device according to the first embodiment.

FIG. 18 is a diagram illustrating a snapback phenomenon of the semiconductor device.

FIG. 19 is a diagram illustrating a relationship between a collector-emitter breakdown voltage and a flaw depth of the semiconductor device.

FIG. 20 is a diagram illustrating a method for manufacturing a semiconductor device according to a modification.

FIG. 21 is a diagram illustrating a crystal defect density distribution and a hydrogen ion donor density distribution of the semiconductor device according to the modification.

FIG. 22 is a cross-sectional view of the semiconductor device according to the modification.

FIG. 23 is a cross-sectional view of a semiconductor device according to a second embodiment.

FIG. 24 is a diagram illustrating a crystal defect density distribution and a hydrogen ion donor density distribution of the semiconductor device according to the second embodiment.

FIG. 25 is a diagram illustrating the crystal defect density distribution and the hydrogen ion donor density distribution of the semiconductor device according to the second embodiment.

FIG. 26 is a diagram illustrating current values and voltage values upon diode reverse recovery of a semiconductor device according to the second embodiment and a semiconductor device according to a conventional example.

### DETAILED DESCRIPTION OF EMBODIMENT

A semiconductor device disclosed in the present specification is applicable to a semiconductor device comprising a semiconductor substrate that comprises: an n type drift layer, a p type body layer on an upper surface side of the drift layer, and a high impurity n layer on a lower surface side of the drift layer, the high impurity n layer having a higher density of n type impurities than the drift layer. Although not particularly limited, for example, the semiconductor device may be a diode, an IGBT comprising a buffer layer, or an RC-IGBT in which an IGBT and a free wheeling diode are formed on a same semiconductor substrate.

When the semiconductor device is a diode, the high impurity n layer and the body layer respectively function as a cathode and an anode of the diode.

When the semiconductor device is an IGBT, the high impurity n layer is a buffer layer. A p type collector layer is formed on a lower surface of the semiconductor substrate (i.e., a lower surface side of the buffer layer). An n type emitter layer is formed in a part of an upper surface of the body layer. The body layer and the emitter layer are exposed at the upper surface of the semiconductor substrate. An insulated gate that is in contact with the body layer at a portion of the body layer that isolates the emitter layer and the drift layer from each other is formed on the upper surface side of the semiconductor substrate. The IGBT may be a field-stop (FS) type IGBT or a punch-through (PT) type IGBT.

When the semiconductor device is an RC-IGBT in which the IGBT and the free wheeling diode are formed on the same semiconductor substrate, a collector layer or a cathode layer is formed on the lower surface of the semiconductor substrate (i.e., the lower surface side of the drift layer). A buffer layer may sometimes be formed between the collector layer and the drift layer or between the cathode layer and the drift layer. The buffer layer and the cathode layer correspond to the high impurity n layer. A body layer is formed on an upper surface of the semiconductor substrate (i.e., an upper surface side of the drift layer). An emitter layer is formed in a part of an upper surface of the body layer. The body layer and the emitter layer are exposed at the upper surface of the semiconductor substrate. A gate electrode that is in contact with the body layer at a portion of the body layer that isolates the emitter layer and the drift layer from each other is formed on the upper surface side of the semiconductor substrate. The RC-IGBT may be a semiconductor device comprising a diode region in which a diode element is formed and an IGBT region in which an IGBT element is formed, wherein the diode region and the IGBT region are separated from each other. Alternatively, the RC-IGBT may be a semiconductor device in which the upper surface side of the semiconductor substrate has a same structure, the lower surface side of the semiconductor substrate is structured as the collector layer or the cathode layer, and the diode element and the IGBT element coexist

A method for manufacturing a semiconductor device disclosed in the present specification comprises, as steps for forming a high impurity n layer and crystal defects, preparing, irradiating, and activating. In the preparing, a semiconductor wafer comprising a drift layer is prepared. In the irradiating, hydrogen ions are irradiated to the semiconductor wafer to form crystal defects. In the activating, the hydrogen ions irradiated in the irradiating are activated to form a high impurity n layer, and at least a part of the crystal defects formed in the irradiating is left in the semiconductor wafer (for example, in the high impurity n layer and a part of the drift layer). The preparing, the irradiating, and the activating are performed in this order, and other steps (for example, wafer cleaning or ion implantation) may be performed therebetween.

### First Embodiment

(Semiconductor Device)

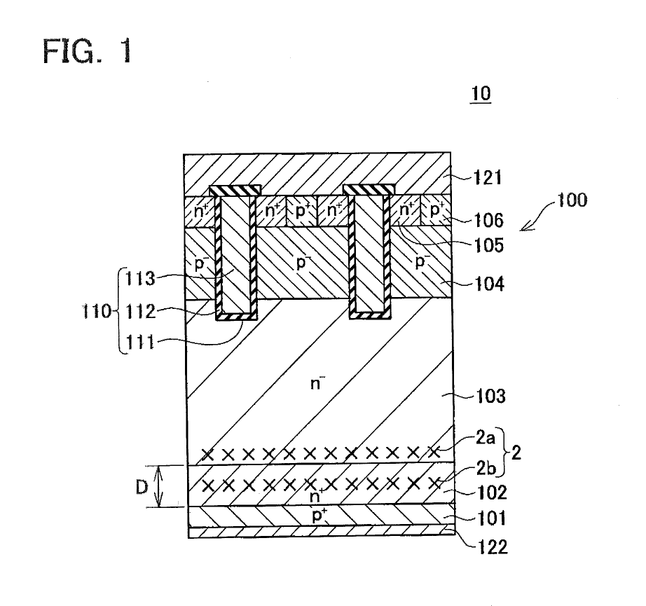

A semiconductor device 10 shown in FIG. 1 is an IGBT comprising a buffer layer 102 as a high impurity n layer. The semiconductor device 10 comprises a semiconductor substrate 100, an emitter electrode 121 provided on an upper surface of the semiconductor substrate 100, and a collector electrode 122 provided on a lower surface of the semiconductor substrate 100. The IGBT is formed on the semiconductor substrate 100. The semiconductor substrate 100 comprises, in order from the lower surface side of the semiconductor substrate 100, a p type collector layer 101, an n type buffer layer 102, an n type drift layer 103, a p type body layer 104, n type emitter layers 105 and a p type body contact layer 106. The emitter layers 105 and the body contact layer 106 are isolated from the drift layer 103 by the body layer 104. The semiconductor substrate 100 further comprises insulated gates 110 in contact with the body layer 104 that is positioned between the emitter layers 105 and the drift layer 103. Each of the insulated gate 110 comprises a trench 111, an insulating film 112 formed on an inner wall of the trench 111, and an gate electrode 113 which is covered by the insulating film 112 and which is formed inside of the trench 111.

The collector layer 101 and the body contact layer 106 have higher densities of p type impurities than the body layer 104. The buffer layer 102 is provided between the drift layer 103 and the collector layer 101 and has a higher density of xi type impurities than the drift layer 103. The buffer layer 102 includes hydrogen ion donors. A lifetime control region 2 with a high density of crystal defects is formed in the buffer layer 102 and the drift layer 103. A hydrogen ion donor density of the buffer layer 102 is favorably between 1×10¹⁴ and 1×10¹⁶ atoms/cm³. The lifetime control region 2 is formed in an entirety of the buffer layer 102 and a part of a buffer layer side of the drift layer 103. The lifetime control region 2 comprises a region 2a included in the drift layer 103 and a region 2b included in the buffer layer 102. A width of the lifetime control region 2 in a depth direction of the semiconductor substrate 100 is greater than a width of the buffer layer 102 in the depth direction of the semiconductor substrate 100 (which corresponds to a thickness of the buffer layer 102). An average crystal defect density of the lifetime control region 2 is significantly higher than a crystal defect density of a portion of the drift layer 103 not included in the lifetime control region 2. A peak of crystal defect density is included in the lifetime control region 2. A crystal defect peak density of the lifetime control region 2 is 1×10¹² atoms/cm³ or more. Accordingly, the lifetime control region 2 is able to sufficiently produce an effect of improving characteristics (for example, a reduction in switching loss) of the semiconductor device 10. The crystal defect density and an amount of crystal defects in the lifetime control region 2 are adjusted so that a lifetime of carriers (e.g., holes that are minority carriers) in the lifetime control region 2 is 1/1000 or more and 1/10 or less of a lifetime of carriers in the portion of the drift layer 103 not included in the lifetime control region 2. In addition, favorably, a width D of the buffer layer 102 in the depth direction of the semiconductor substrate 100 is 2 μm or more and 70 μm or less.

(Method for Manufacturing Semiconductor Device)

A method for manufacturing the semiconductor device 10 will be described with a focus on steps for forming the buffer layer 102 and the lifetime control region 2. Since other components of the semiconductor device 10 can be formed using conventionally known methods, a description thereof will be omitted. Steps for forming the buffer layer 102 and the lifetime control region 2 include preparing, irradiating, and activating. In the preparing, a semiconductor wafer comprising the drift layer 103 is prepared. In the irradiating, hydrogen ions are irradiated to the semiconductor wafer to form crystal defects. In the activating, the hydrogen ions irradiated in the irradiating are activated. Accordingly, the buffer layer 102 is formed and, at the same time, at least a part of the crystal defects formed in the irradiating is left in the buffer layer 102 and a part of the drift layer 103.

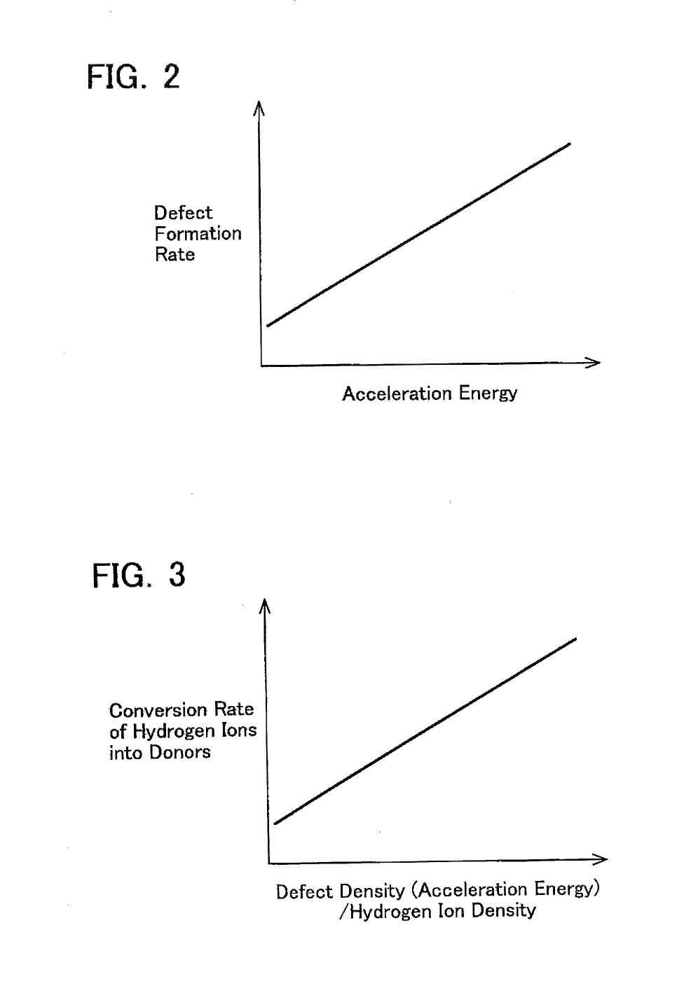

An acceleration energy of the hydrogen ions in the irradiating will now be described in greater detail. In the irradiating, crystal defects are formed by irradiating the hydrogen ions to the drift layer of the semiconductor substrate at an acceleration energy of 2 MeV or more. As shown in FIG. 2, the higher the acceleration energy (represented by an abscissa in FIG. 2) of the hydrogen ions irradiated in the irradiating, the higher a defect formation rate (represented by an ordinate in FIG. 2) that is a rate at which the crystal defects are formed. In other words, the higher the acceleration energy of hydrogen ions, the higher a “defect density/hydrogen ion density” that is a ratio between crystal defect density and hydrogen ion density.

In the activating, hydrogen ions irradiated in the irradiating are activated by annealing or the like. It is presumed that hydrogen ions are converted into donors by a composition of irradiated hydrogen ions, silicon (Si) in the semiconductor substrate, and crystal defects formed by the irradiation of the hydrogen ions. As shown in FIG. 3, the higher the “defect density/hydrogen ion density (represented by an abscissa in FIG. 3)”, the higher a conversion rate of hydrogen ions into donors (represented by an ordinate in FIG. 3). As shown in FIG. 2, the higher the acceleration energy of hydrogen ions irradiated in the irradiating, the higher the “defect density/hydrogen ion density”. Therefore, the higher the acceleration energy, the higher the conversion rate of hydrogen ions into donors.

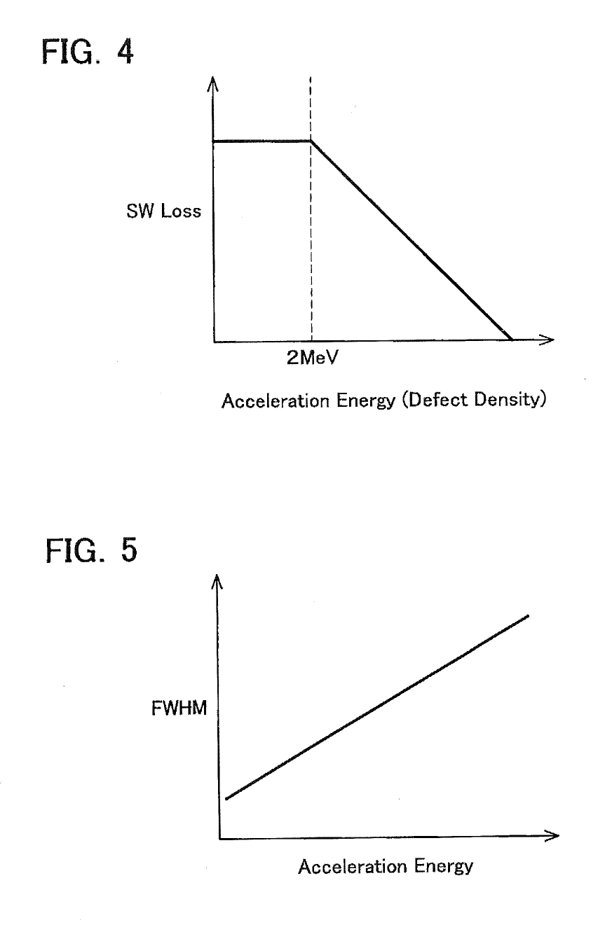

In addition, the higher the acceleration energy of hydrogen ions irradiated in the irradiating, the higher a peak density of the crystal defects in the lifetime control region 2. The crystal defect peak density of the lifetime control region 2 of 1×10¹² atoms/cm³ or more is required by the lifetime control region 2 to produce an effect of reducing switching loss of the semiconductor device 10. In the irradiating, when hydrogen ions are irradiated at an acceleration energy of 2 MeV, the crystal defect peak density of the lifetime control region 2 is 1×10¹² atoms/cm³. As shown in FIG. 4, when a value of the acceleration energy of the irradiated hydrogen ions is 2 MeV or more (in other words, when the crystal defect peak density is 1×10¹² atoms/cm³ or more), the higher the acceleration energy (represented by an abscissa in FIG. 4), the greater an effect of the lifetime control region 2 of reducing switching loss (represented by an ordinate in FIG. 4). On the other hand, when the value of the acceleration energy of the irradiated hydrogen ions is less than 2 MeV (in other words, when the crystal defect peak density is less than 1×10¹² atoms/cm³), the effect of reducing the switching loss cannot be produced.

Furthermore, as shown in FIG. 5, the higher the acceleration energy (represented by an abscissa in FIG. 5) of the hydrogen ions irradiated in the irradiating, the greater a full width at half maximum (FWHM) of the density of hydrogen ions that have been converted into donors (represented by an ordinate in FIG. 5). For example, when the acceleration energy of the hydrogen ions is around 2 MeV, 4 MeV, 8 MeV, and 20 MeV, the FWHM of the density of hydrogen ions converted into donors is respectively around 2 μm, 7 μm, 20 μm, and 70 μm. In other words, the higher the acceleration energy of the irradiated hydrogen ions, the greater a thickness of the buffer layer 102 formed by converting hydrogen ions into donors. Therefore, there is no need to perform annealing or the like at a high temperature (around 900 degrees Celsius) at which such annealing or the like is normally performed in order to ensure the thickness of the buffer layer 102. For example, when a value of an acceleration energy of the irradiated hydrogen ions is 2 MeV or more, the buffer layer 102 can be formed with a thickness of 2 μm or more by performing annealing at a wafer temperature of 200 degrees Celsius or more and 500 degrees Celsius or less.

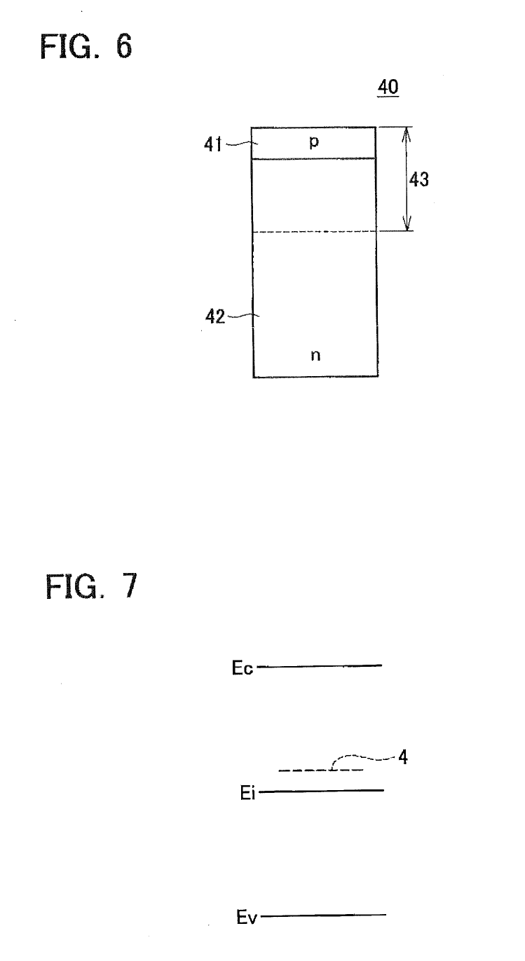

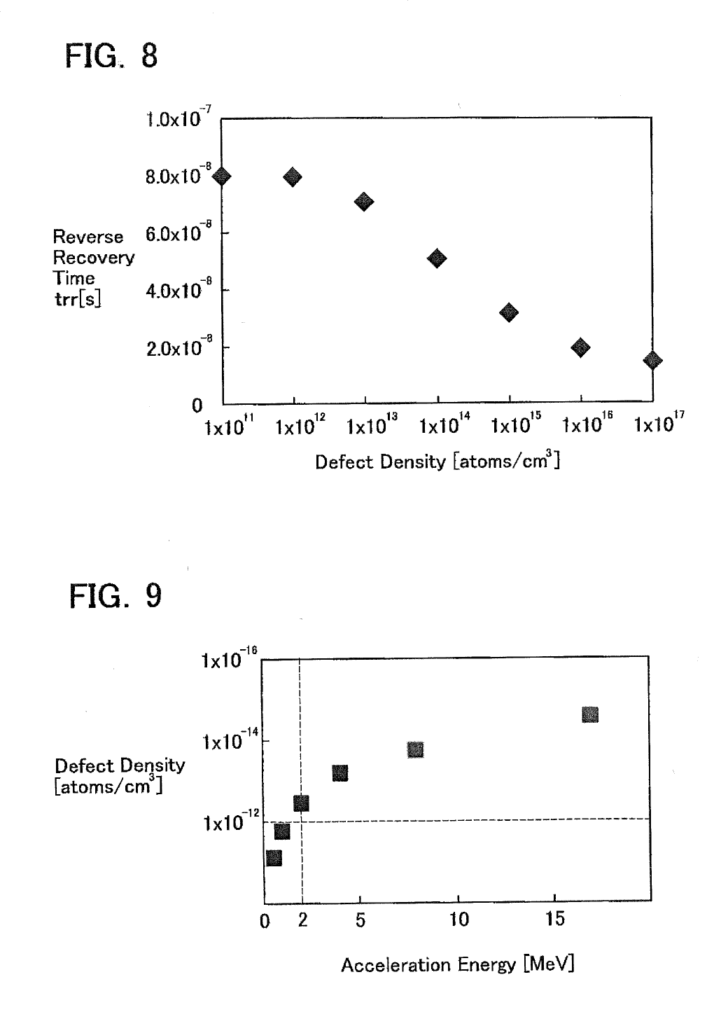

FIGS. 6 to 9 are diagrams showing a result of a simulation performed with a semiconductor device on which a diode element is formed. As shown in FIG. 6, a diode 40 which comprises a semiconductor substrate comprising a p type semiconductor layer 41 and an n type semiconductor layer 42 and in which crystal defects are formed in a region 43 was used for the simulation. FIG. 7 shows a band gap structure of the diode 40. A Fermi level Ei is located in a forbidden band between a conduction band Ec and a valence band Ev. As shown in FIG. 7, a level 4 of the crystal defects is slightly higher than the Fermi level. In the simulation, a relationship between a crystal defect peak density and switching characteristics of the diode 40 was studied by varying the crystal defect peak density. A result of the simulation is shown in FIG. 8. Plot points shown in FIG. 8 respectively represent crystal defect peak densities of the diode 40 of 1×10¹¹ atoms/cm³, 1×10¹² atoms/cm³, 1×10¹³ atoms/cm³, 1×10¹⁴ atoms/cm³, 1×10¹⁵ atoms/cm³, 1×10¹⁶ atoms/cm³, and 1×10¹⁷ atoms/cm³. As shown in FIG. 8, it was found that when the crystal defect peak density of the diode 40 is 1×10¹² atoms/cm³ or more, the higher the crystal defect peak density, the shorter a reverse recovery time trr of the diode 40. In addition, FIG. 9 shows a result of a simulation performed regarding the acceleration energy of the hydrogen ions irradiated in the irradiating and the peak density of crystal defects of the semiconductor device formed in the diode 40 by the irradiating. As shown in FIG. 9, the higher the acceleration energy, the higher the crystal defect peak density. With the acceleration energy of 2 MeV or more, the crystal defect peak density can be set to 1×10¹² atoms/cm³ or more. Since the shorter the reverse recovery time trr of the diode 40, the smaller the switching loss (sometimes abbreviated as SW loss) of the diode, the relationship between the acceleration energy and the switching loss shown in FIG. 4 can be obtained from the results shown in FIGS. 8 and 9.

As described above, the acceleration energy of the hydrogen ions irradiated in the irradiating is 2 MeV or more. When the acceleration energy of the hydrogen ions is 2 MeV or more, by subsequently performing activating, the lifetime control region 2 having the effect of reducing the switching loss can be formed and, at the same time, the buffer layer 102 can be formed with the thickness of 2 μm or more. More favorably, the acceleration energy of the hydrogen ions is 2 MeV or more and 20 MeV or less. By irradiating the hydrogen ions at the acceleration energy of 20 MeV or less, a function of the lifetime control region of reducing the carrier lifetime can be sufficiently produced. On the other hand, if the acceleration energy exceeds 20 MeV, a load on an apparatus for irradiating the hydrogen ions increases, resulting in a higher manufacturing cost.

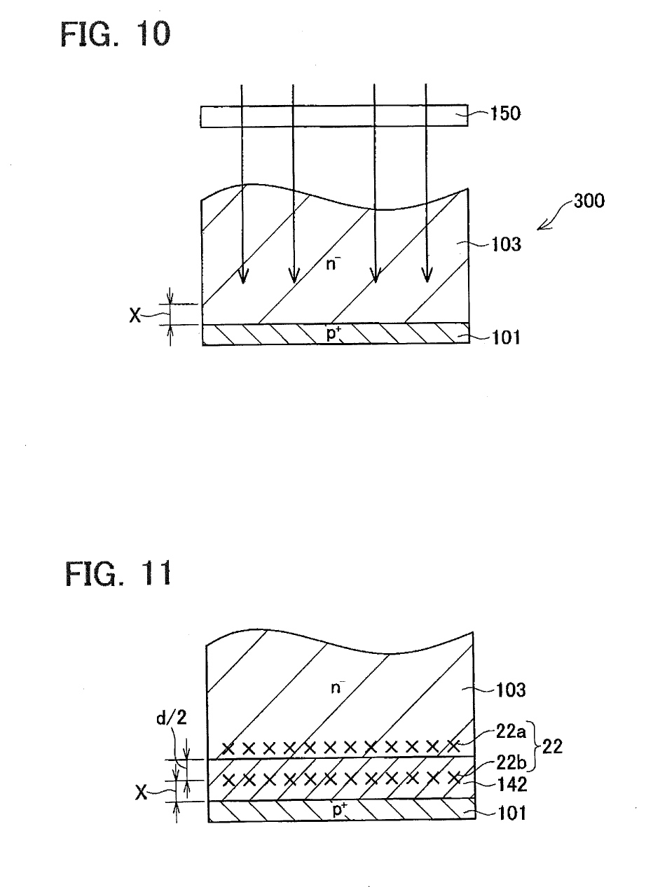

Hereinafter, an example of a method for manufacturing the semiconductor device 10 will be described in greater detail with reference to FIGS. 10 to 14. As shown in FIG. 10, in preparing, a semiconductor substrate 300 comprising the drift layer 103 and the collector layer 101 in contact with the lower surface of the drift layer 103 is prepared. While the structure of the semiconductor substrate 300 on the upper surface side relative to the drift layer 103 is omitted in FIG. 10, the respective components of the semiconductor device 10 shown in FIG. 1 are formed on an upper surface side of the drift layer 103. When an n type semiconductor wafer is used as the drift layer 103, structures of the collector layer, the body layer, and the like can be formed by performing ion implantation or the like on the n type semiconductor wafer. In addition, when a p type semiconductor wafer is used as the collector layer 101, structures of the body layer and the like may be formed by forming an n type epitaxial layer as the drift layer 103 on an upper surface of the p type semiconductor wafer and then performing ion implantation or the like on the epitaxial layer.

As shown in FIG. 10, in the irradiating, the hydrogen ions are irradiated via an absorber 150 to a region of the drift layer 103 on a side of the collector layer 101 at the acceleration energy of 2 MeV or more. FIG. 10 illustrates a case in which the hydrogen ions are irradiated from the upper surface side of the semiconductor substrate 300. The hydrogen ions are favorably irradiated using an accelerator capable of achieving a high acceleration energy with relative ease. For example, a cyclotron accelerator can be favorably used. An irradiating position (i.e., an average stop position of the hydrogen ions) is set to a position at a distance X (X≧0) from the upper surface of the collector layer 101. The irradiating position can be adjusted to a predetermined position by adjusting the acceleration energy of the irradiated hydrogen ions and a thickness of the absorber 150. The irradiance level of the hydrogen ions is favorably 5×10¹³ cm⁻² or more and 1×10¹⁶ cm⁻² or less.

Accordingly, as shown in FIG. 11, an ion layer 142 in which the hydrogen ions are irradiated and a region 22 in which crystal defects are formed can be formed so as to come into contact with the upper surface side of the collector layer 101. The region 22 comprises a region 22a included in the drift layer 103 and a region 22b included in the ion layer 142. The peak of crystal defect density is located in the region 22b.

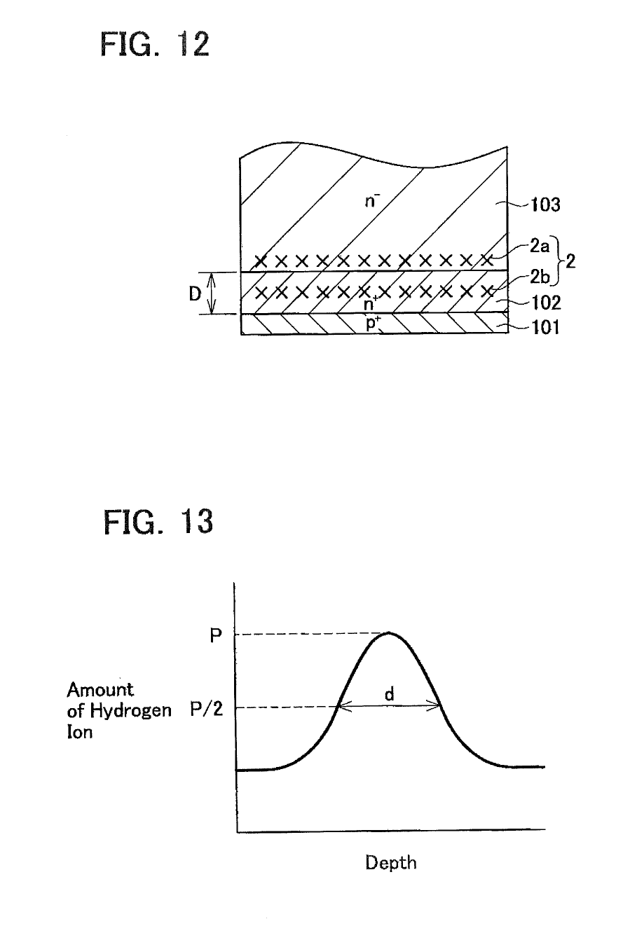

As shown in FIG. 12, in the activating, the hydrogen ions irradiated in the irradiating are activated to convert the hydrogen ions into hydrogen ion donors in order to form the buffer layer 102. In the activating, the hydrogen ions are activated by annealing the semiconductor substrate 300. The annealing involves heating in a temperature range of 200 degrees Celsius or more and 500 degrees Celsius or less in an nitrogen atmosphere. By performing annealing, a composition of the crystal defects formed by the irradiation of the hydrogen ions, the hydrogen ions, and silicon (Si) occurs and the hydrogen ions are converted into the donors. Accordingly, as shown in FIG. 12, a buffer layer can be formed between the collector layer 101 and the drift layer 103. In addition, after performing annealing, the crystal defects formed in the irradiating are left in the buffer layer 102 and the drift layer 103. Accordingly, as shown in FIG. 12, the lifetime control region 2 is formed in the buffer layer 102 and in a part of the drift layer 103 on a side of the collector layer 101.

As shown in FIG. 13, the amount of the hydrogen ions irradiated in the irradiating has a symmetrical pattern in the depth direction centered at a peak position of the amount of the hydrogen ions. If P denotes the peak of the amount of the hydrogen ions represented by an ordinate, then a width of a region having the amount of the hydrogen ions of P/2 or more in the depth direction of the semiconductor substrate may be denoted by d. In other words, d denotes the FWHM of a waveform shown in FIG. 13. The irradiating position X shown in FIGS. 10 and 11 is set so as to satisfy X<d/2. As shown in FIG. 11, the ion layer 142 extends from the irradiating position X for a distance d/2 toward the upper surface side of the semiconductor substrate. By setting the irradiating position X so as to satisfy X<d/2, the ion layer 142 having the amount of the hydrogen ions of P/2 or more can be formed in contact with the upper surface side of the collector layer 101.

Moreover, by adjusting irradiating conditions of the hydrogen ions (e.g., the irradiance level of the hydrogen ions, the acceleration energy, and the like) during the irradiating and adjusting annealing conditions (e.g., the annealing temperature, the heating method, and the like) during the activating, the peak position, the peak density, the FWHM, and the like of a density distribution curve of the hydrogen ion donors and a density distribution curve of the crystal defects can be adjusted. In addition, the irradiation of the hydrogen ions can be performed in two or more stages as necessary. When performing the irradiation of the hydrogen ions in two or more stages, an irradiating position and an irradiating direction may be varied among the irradiation stages.

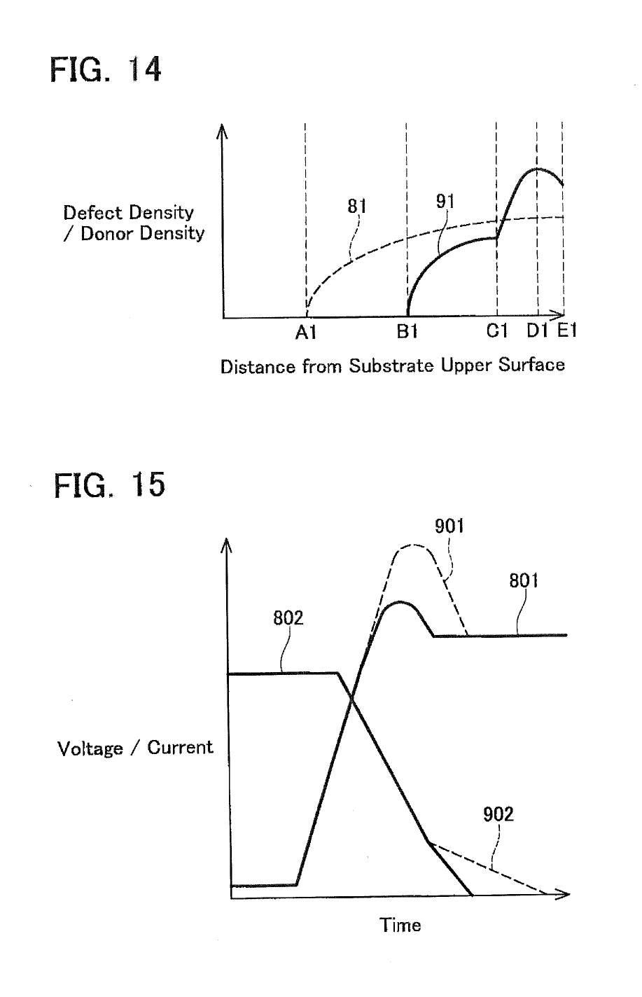

FIG. 14 is a diagram in which the distribution of the crystal defect density and the distribution of the hydrogen ion donor density are plotted with respect to distances from the upper surface of the semiconductor substrate 300 in a case in which the irradiating position X is set to 0 (in FIG. 10, when a position of an interface between the collector layer 101 and the drift layer 103 is set to the irradiating position of the hydrogen ions). The crystal defect density is represented by a dashed line denoted by reference numeral 81 and the hydrogen ion donor density is represented by a solid line denoted by reference numeral 91. A region between distances D1 and E1 is the collector layer 101. A region between distances B1 and D1 is the buffer layer 102. A region shallower than distance B1 (on the upper surface side of the semiconductor substrate 300) is the drift layer 103. When hydrogen ions are irradiated from the upper surface side of the semiconductor substrate 300 to a position of distance D1, a Gaussian-like distribution of hydrogen ion donor density depicted between distances D1 and C1 can be obtained according to the FWHM determined by the acceleration energy. This distribution is consistent with the density distribution of the hydrogen ions formed upon the irradiation of the hydrogen ions. In the region between distances C1 and B1, the hydrogen ion donors are distributed more gradually than in the region between distances D1 and C1. The hydrogen ion donors are distributed more gradually in the region between distances C1 and B1 due to a diffusion of the hydrogen ions caused by the activation such as the annealing in the activating. The crystal defects are spread in the region between distances A1 and E1. Since the irradiation of hydrogen ions is performed at the high acceleration energy of 2 MeV or more, the crystal defects are readily formed even in the regions through which the hydrogen ions pass. Therefore, the crystal defects are gradually distributed across a wide range such as shown in FIG. 14.

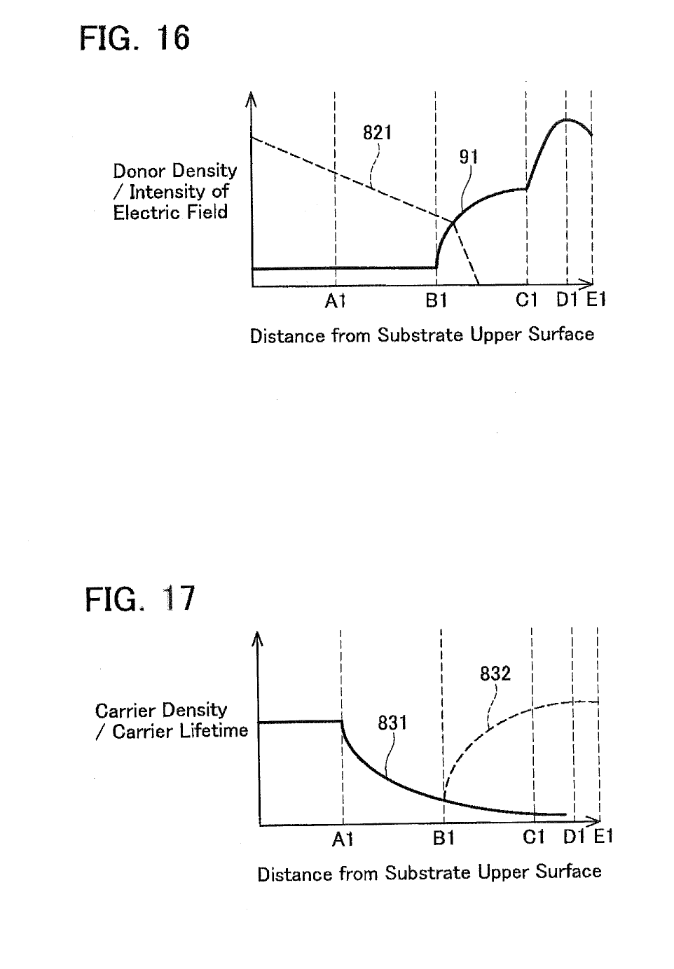

The region between distances C1 and D1 has the high hydrogen ion donor density and effectively suppresses a rapid expansion of an electric field when a high voltage is applied to the semiconductor device 10. The region between distances C1 and D1 is consecutive to the region between distances B1 and C1 which has the gradual distribution, and has an effect of making an overall spread of the electric field more gradual and causing the carriers to dissipate slowly upon turnoff. FIG. 15 shows current values and voltage values upon turnoff of semiconductor devices. As shown in FIG. 15, compared to a voltage value (reference numeral 901) of a conventional semiconductor device, with a voltage value (reference numeral 801) of the semiconductor device 10 having the donor distribution such as that shown in FIG. 14, a surge voltage upon turnoff is reduced. A mechanism in which the surge voltage is reduced will now be described in detail. With the semiconductor device 10 having the donor distribution such as that shown in FIG. 14, as shown in FIG. 16, an intensity (reference numeral 821) of the electric field formed upon the turnoff is significantly reduced by the hydrogen ion donors (reference numeral 91) that are distributed at a high density in the region between distances B1 and E1. In addition, as shown in FIG. 17, upon the turnoff, a carrier density (reference numeral 832) increases in the region between distances B1 and El. As a result, the carriers left in the drift layer 103 dissipate rapidly and the switching loss is reduced.

Furthermore, in the region between distances Al and El, the crystal defects are gradually distributed with distance D1 as the peak position. The crystal defect density distribution has an effect of causing excessively implanted electrons and holes to dissipate. As shown in FIG. 15, compared to a current value (reference numeral 902) of a conventional semiconductor device, with a current value (reference numeral 802) of the semiconductor device 10 having the crystal defect density distribution such as that shown in FIG. 14, a tail current upon the turnoff is reduced. As a result, the switching loss can be reduced. In particular, in the region between distances A1 to B1, while the crystal defects are formed, the hydrogen ion donors are not formed. Therefore, in the region between distances A1 to B1, the crystal defects have a significant effect of causing the carriers to dissipate. Since the semiconductor device having the distribution shown in FIG. 14 has a region in which the crystal defects are distributed but the hydrogen ion donors are substantially not distributed, the semiconductor device having the distribution shown in FIG. 14 produces a significant effect of reducing the switching loss and can be favorably used in applications in which high-speed switching is performed. In addition, as shown in FIG. 17, the greater the amount of the crystal defects distributed in a region, the shorter the lifetime of the carriers in the region as depicted by reference numeral 831. The carriers have a shorter lifetime on the lower surface side of the semiconductor substrate that has more residual carriers (reference numeral 832), and the carriers have a longer lifetime on the upper surface side of the semiconductor substrate that has fewer residual carriers. In other words, the carriers remaining between distances B1 to E1 have a short lifetime and rapidly dissipate. As a result, the switching loss is reduced.

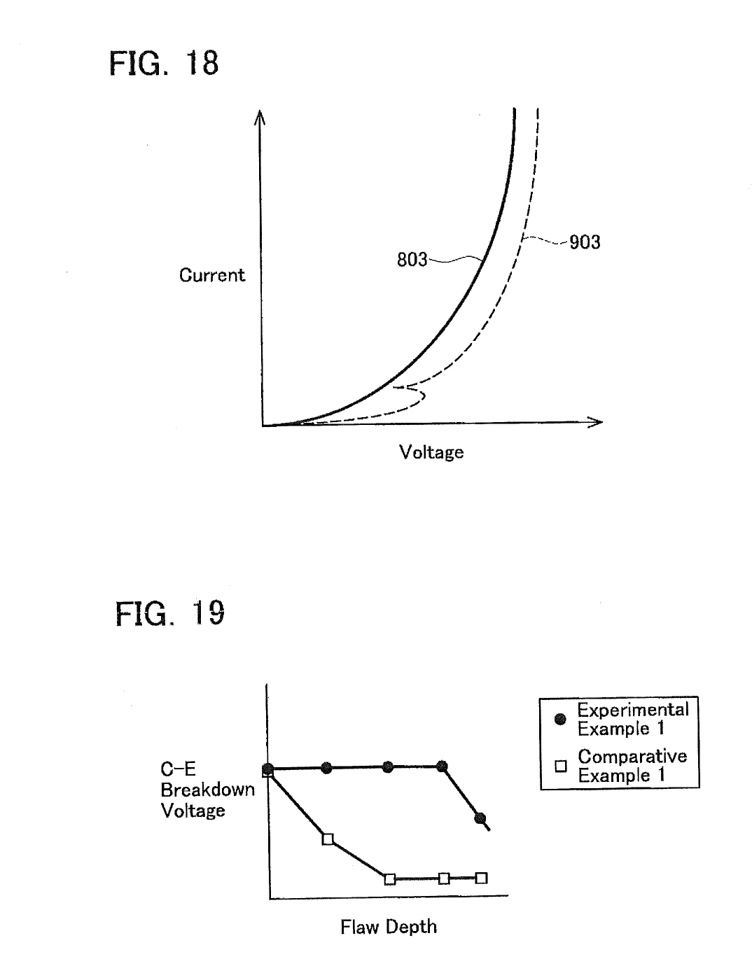

Furthermore, the semiconductor device according to the present teachings also provides an effect of preventing a snapback phenomenon of an on voltage. FIG. 18 shows a normal waveform 803 when the semiconductor device is turned on, and a snapback waveform 903 indicating that a snapback phenomenon has occurred. As shown in FIG. 18, the snapback waveform 930 shows that, when the semiconductor device 10 is turned on, a current initially increases as an applied voltage increases, but once the applied voltage reaches a specific switching voltage, the phenomenon temporarily occurs in which a current value decreases as the applied voltage increases (negative resistance). In addition, when the applied voltage subsequently further increases and reaches a specific holding voltage, the current increases once again. In the semiconductor device and the method for manufacturing the semiconductor device according to the present teachings, hydrogen ions are irradiated and converted into donors to form a high impurity n layer, and the lifetime control region is formed in and around the high impurity n layer. Therefore, the semiconductor device according to the present teachings is capable of producing the effect of reducing the tail current during turn off such as shown in FIG. 11 and reducing the switching loss even if the crystal defect density of the lifetime control region is relatively low. With the semiconductor device according to the present teachings, since the crystal defect density of the lifetime control region can be relatively lowered, the snapback is less likely to occur.

Furthermore, according to the manufacturing method described above, a width D of the buffer layer 102 of the semiconductor device 10 in the depth direction of the semiconductor substrate 100 can be set to 2 μm or more and 70 μm or less. Therefore, a decline in collector-emitter breakdown voltage due to flaws created on a lower surface of the semiconductor device can be suppressed. FIG. 19 shows a breakdown voltage between a collector electrode and an emitter electrode (i.e., a collector-emitter breakdown voltage) when a flaw is created on a lower surface (a collector layer side) of an IGBT comprising a buffer layer. The further rightward on an abscissa, the deeper a flaw created on the lower surface of the semiconductor device. Experimental data denoted as Experimental example 1 represents a case in which the buffer layer 102 of the semiconductor device 10 has a thickness of 2 μm. Data denoted as Comparative example I represents a case of a semiconductor device configured similar to that of Experimental example 1 with the exception of a buffer layer having a thickness of 1 μm. As shown in FIG. 19, in Comparative example 1, a collector-emitter breakdown voltage declined significantly when a flaw was created on the lower surface of the semiconductor device. On the other hand, in Experimental example 1, a collector-emitter breakdown voltage did not decline when a depth of a flaw was under a certain depth. With the semiconductor device according to Experimental example 1, a decline in the collector-emitter breakdown voltage due to the flaw created on the lower surface of the semiconductor device can be suppressed. Although the thicker the buffer layer 102, the greater the effect of suppressing the decline in the collector-emitter breakdown voltage due to the flaw created on the lower surface, a resistance value during IGBT operation increases if the buffer layer 102 is excessively thick. Therefore, the width D of the buffer layer 102 in the depth direction of the semiconductor substrate 100 is 2 μm or more and 70 μm or less.

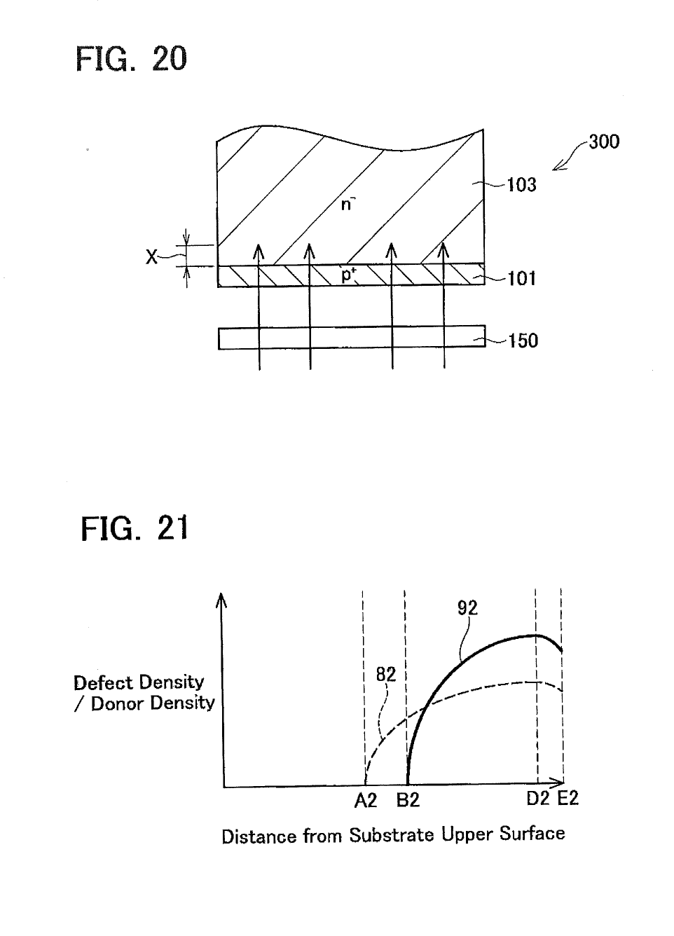

While a case in which the hydrogen ions are irradiated from the upper surface side of the semiconductor substrate 300 (FIG. 10) in the irradiating has been exemplified and described above, as shown in FIG. 20, the hydrogen ions may alternatively be irradiated from the lower surface side of the semiconductor substrate 300. When the hydrogen ions are irradiated from the lower surface side in the irradiating, the crystal defect density distribution and the hydrogen ion donor density distribution may be plotted with respect to the distance from the upper surface of the semiconductor substrate 300 as shown in FIG. 21. The crystal defect density is represented by a dashed line denoted by reference numeral 82 and the hydrogen ion donor density is represented by a solid line denoted by reference numeral 92. A region between distances D2 and E2 is the collector layer 101. A region between distances B2 and D2 is the buffer layer 102. A region shallower than distance B2 is the drift layer 103. When hydrogen ions are irradiated from the upper surface side of the semiconductor substrate 300 to a position of distance D2, a Gaussian-like distribution of donor density depicted between distances D2 and B2 can be obtained according to the FWHM determined by the acceleration energy. The density distribution of the hydrogen ion donors is consistent with the distribution of hydrogen ions formed upon the hydrogen ion irradiation, and has the Gaussian-like pattern which is distributed between the distances B2 and E2 and which is in accordance with the FWHM determined by the acceleration energy of the irradiated hydrogen ions.

The crystal defects spread across a region between distances A2 to E2 and are distributed in a region wider in the depth direction of the semiconductor substrate 300 than the hydrogen ion donors. As shown in FIGS. 2 and 3, while the rate of formation of the crystal defects and the rate of the hydrogen ions converted into donors are dependent on the acceleration energy of the hydrogen ions, the former rate is higher than the latter rate at a same acceleration energy. For example, in a case in which the hydrogen ions are irradiated at the acceleration energy of 2 MeV, while 30 crystal defects are formed for every hydrogen ion, the rate of the hydrogen ions converted into donors is around one donor for every 10 hydrogen ions. The crystal defects have a relatively high density even in regions irradiated with a small amount of hydrogen ions. On the other hand, the hydrogen ion donors have a relatively low density in regions irradiated with a small amount of hydrogen ions, sometimes to the extent of being negligible. As a result, the crystal defects become distributed in a region that is wider in the depth direction of the semiconductor substrate than the hydrogen ion donors.

A case in which the semiconductor device 10 has a distribution shown in FIG. 21 will be described. A region between distances B2 and E2 has a distribution of a high density of the hydrogen ion donors and effectively suppresses the rapid expansion of the electric field when a high voltage is applied to the semiconductor device 10. In addition, the hydrogen ion donors are gradually distributed overall in the region between distances B2 and E2. Therefore, the effect of causing the electric field to spread gradually and causing the carriers during the turn-off to dissipate slowly is produced. Even with the semiconductor device having the hydrogen ion donor density distribution such as shown in FIG. 21, the effect of reducing the surge voltage such as shown in FIG. 15 can be produced in a similar manner to the case shown in FIG. 14. In addition, the snapback phenomenon such as shown in FIG. 18 can be prevented. Furthermore, in a similar manner to FIG. 10, in FIG. 21, in a region between distances A2 and E2, the crystal defects are gradually distributed with distance D2 as the peak position. As a result, the effect of reducing the tail current such as shown in FIG. 15 can be produced.

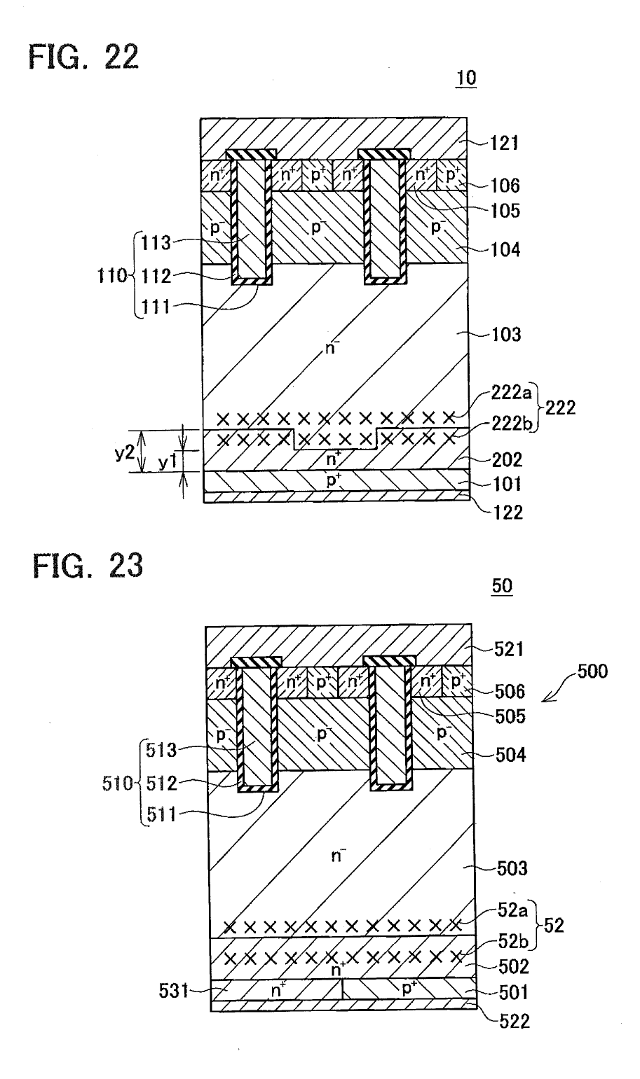

Moreover, buffer layers are not limited to those with flat upper and lower surfaces as is the case of the buffer layer 102 shown in FIG. 1. For example, a buffer layer 202 having irregularities on a surface in contact with the drift layer 103 such as shown in FIG. 22 may be adopted. In this case, a design is adopted in which both a width y1 in a depth direction of a thin portion of the buffer layer 202 and a width y2 in a depth direction of a thick portion of the buffer layer 202 are within a range shown with respect to the width D described earlier. A lifetime control region 222 comprises a region 222a and a region 222b. The region 222a is included in the drift layer 103 and the region 222b is included in the buffer layer 202.

### Second Embodiment

The semiconductor device according to the present teachings is not limited to the IGBT and may instead be a diode, a MOSFET, an RC-IGBT, or the like. As one alternative example, a semiconductor device 50 shown in FIG. 23 will be described. The semiconductor device 50 is an RC-IGBT comprising a buffer layer 502 and a cathode layer 531 as a high impurity n layer. The semiconductor device 50 comprises a semiconductor substrate 500, an upper surface electrode 521 provided on an upper surface of the semiconductor substrate 500, and a lower surface electrode 522 provided on a lower surface of the semiconductor substrate 500. An IGBT and a diode are formed on the semiconductor substrate 500. The semiconductor substrate 500 comprises, in order from the lower surface side of the semiconductor substrate 500, a p type collector layer 501 and an n type cathode layer 531, an n type buffer layer 502, an n type drift layer 503, a p type body layer 504, and n type emitter layers 505 and a p type body contact layer 506. The emitter layers 505 and the body contact layer 506 are isolated from the drift layer 503 by the body layer 504. The semiconductor substrate 500 further comprises insulated gates 510 in contact with the body layer 504 that is positioned between the emitter layers 505 and the drift layer 503. Each of the insulated gate 510 comprises a trench 511, an insulating film 512 formed on an inner wall of the trench 511, and an gate electrode 513 which is covered by the insulating film 512 and which is formed inside of the trench 511. The buffer layer 502 is provided between the drift layer 503 and the collector layer 501. The cathode layer 531 and the collector layer 501 are adjacent to each other. The collector layer 501 and the body contact layer 506 have higher densities of p type impurities than the body layer 504. The buffer layer 502 has a higher density of n type impurities than the drift layer 503, and the cathode layer 531 has a higher density of n type impurities than the buffer layer 502. The buffer layer 502 includes hydrogen ion donors. A lifetime control region 52 with a high density of crystal defects is formed in the buffer layer 502 and the drift layer 503. The lifetime control region 52 comprises a region 52a included in the drift layer 503 and a region 52b included in the buffer layer 502. A crystal defect peak density of the lifetime control region 52 is 1×10¹² atoms/cm³ or more.

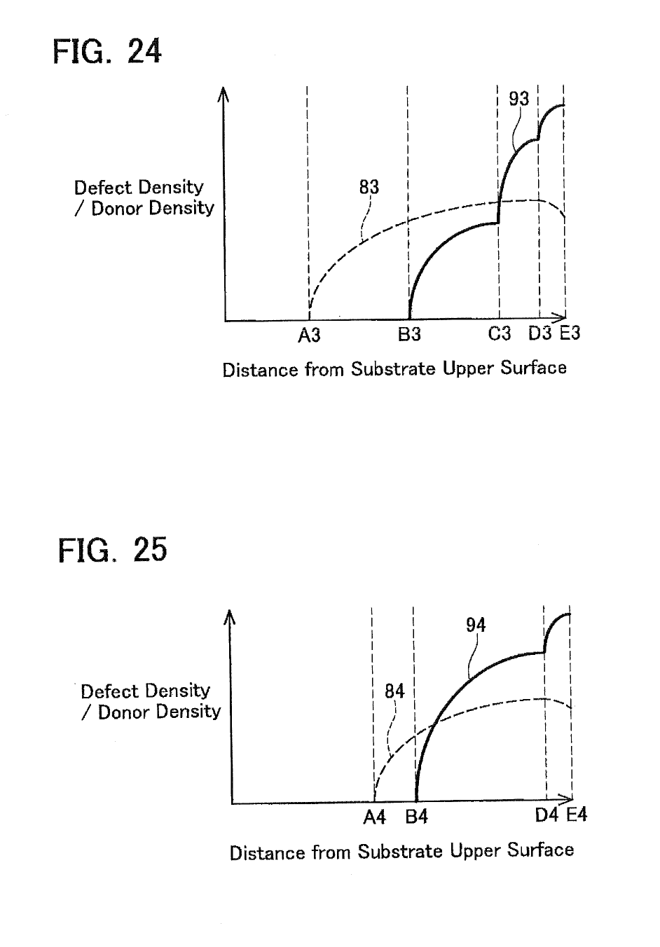

FIGS. 24 and 25 are diagrams in which a distribution of crystal defect density and a distribution of hydrogen ion donor density of the semiconductor device 50 in a portion in which the cathode layer 531 is formed on a lower surface are plotted with respect to distances from the upper surface of the semiconductor substrate 500. FIG. 24 shows distributions in a case in which the hydrogen ions are irradiated from an upper surface side of a semiconductor substrate in the irradiating in a similar manner to FIG. 10. FIG. 25 shows distributions in a case in which the hydrogen ions are irradiated from a lower surface side of the semiconductor substrate in the irradiating in a similar manner to FIG. 20. Moreover, the distribution of crystal defect density and the distribution of hydrogen ion donor density of the semiconductor device 50 in a portion in which the collector layer 501 is formed on the lower surface are similar to the distributions shown in FIGS. 14 and 21.

In FIG. 24, the crystal defect density is represented by a dashed line denoted by reference numeral 83 and the hydrogen ion donor density is represented by a solid line denoted by reference numeral 93. A region between distances D3 and E3 is the cathode layer 531. A region between distances B3 and D3 is the buffer layer 502. A region shallower than distance B3 is the drift layer 503. When hydrogen ions are irradiated from the upper surface side of the semiconductor substrate 500 to a position of distance D3, a Gaussian-like distribution of the hydrogen ion donor density depicted between distances D3 and C3 can be obtained according to a FWHM determined by an acceleration energy. This distribution is consistent with the distribution of the hydrogen ions formed upon the irradiation of the hydrogen ions. In the region between distances C3 and B3, the hydrogen ion donors are distributed more gradually than in the region between distances D3 and C3. The hydrogen ion donors are distributed more gradually in the region between distances C3 and B3 due to a diffusion of the hydrogen ions caused by activation such as annealing in the activating. The crystal defects are spread in a region between distances A3 and E3.

In FIG. 25, the crystal defect density is represented by a dashed line denoted by reference numeral 84, and the hydrogen ion donor density is represented by a solid line denoted by reference numeral 94. A region between distances D4 and E4 is the cathode layer 531. A region between distances B4 and D4 is the buffer layer 502. A region shallower than distance B4 is the drift layer 503. When the hydrogen ions are irradiated from the upper surface side of the semiconductor substrate 500 to a position of distance D4, the Gaussian-like distribution of donor density depicted between distances D4 and B4 can be obtained according to the FWHM determined by the acceleration energy. The density distribution of the hydrogen ion donors is consistent with the distribution of the hydrogen ions formed upon the hydrogen ion irradiation, and has the Gaussian-like pattern which is distributed between distances B4 and E4 and which is in accordance with the a FWHM determined by the acceleration energy of the irradiated hydrogen ions. The crystal defects spread across a region between distances A4 to E4 and are distributed in a region wider in the depth direction of the semiconductor substrate than the hydrogen ion donors.

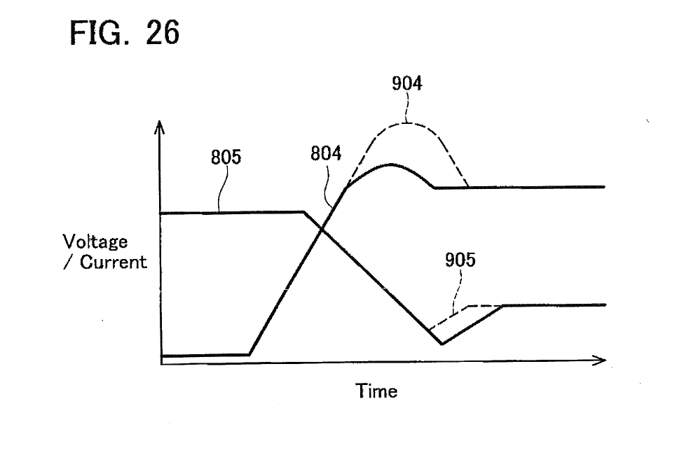

FIG. 26 shows a current value (reference numeral 805) and a voltage value (reference numeral 804) during a reverse recovery (during a recovery) of the diode of the semiconductor device 50. For comparison, FIG. 26 also shows a current value (reference numeral 905) and a voltage value (reference numeral 904) of a conventional semiconductor device. When the semiconductor device 50 has the distribution shown in FIG. 24 or 25, an intensity of an electric field formed during turn-off is reduced by the hydrogen ion donors distributed in high density between the distances B3 and E3 or between the distances B4 and E4 in a similar manner to the case of the semiconductor device 10 described with reference to FIGS. 16 and 17. As a result, as shown in FIG. 26, a recovery surge voltage during a reverse recovery of the diode is reduced. In addition, in a similar manner to the case of the semiconductor device 10 described with reference to FIG. 17, since residual carriers accumulate on the lower surface side of the semiconductor substrate 500, a soft turn-off and a soft recovery can be realized. Furthermore, the greater an amount of the distributed crystal defects in a region, the shorter a lifetime of carriers in the region. Therefore, as shown in FIG. 26, the recovery current can be reduced. Moreover, an effect of the semiconductor device 50 during IGBT operation is as described with respect to the semiconductor device 10 that is the IGBT having the distributions shown in FIGS. 14 and 21. In addition, the effect during the reverse recovery of the diode of the RC-IGBT described above can be produced in a similar manner with the semiconductor device comprising a diode as a semiconductor element (for example, a semiconductor device comprising only a diode as the semiconductor element).

Some of the features of the above embodiments will be described. In the above semiconductor device, favorably, a width of the high impurity n layer in the depth direction of the semiconductor substrate is 2 μm or more and 70 μm or less.

In addition, the present specification also discloses a method for manufacturing a semiconductor device comprising a semiconductor substrate, the semiconductor substrate comprising an n type drift layer, a p type body layer on an upper surface side of the drift layer, and a high impurity n layer on a lower surface side of the drift layer, the high impurity n layer including hydrogen ion donors as a dopant, and having a higher density of n type impurities than the drift layer. The manufacturing method comprises: preparing a semiconductor wafer comprising the drift layer; irradiating hydrogen ions from a surface on a collector layer side of the semiconductor wafer to a region on a collector layer, side the drift layer of the semiconductor wafer at an acceleration energy of 2 MeV or more to form crystal defects; and activating the hydrogen ions irradiated to form the high impurity n layer, and leaving at least a part of the crystal defects formed by the irradiating in the semiconductor wafer.

Favorably, in the irradiating, the hydrogen ions are irradiated to the drift layer of the semiconductor wafer at an acceleration energy of 2 MeV or more and 20 MeV or less. In the irradiating, the hydrogen ions may be irradiated from the lower surface side of the drift layer of the semiconductor wafer or from the upper surface side of the drift layer of the semiconductor wafer. Favorably, the activating includes annealing the semiconductor wafer at a wafer temperature of 200 degrees Celsius or more and 500 degrees Celsius or less.

While embodiments of the present teachings have been described in detail, such embodiments are merely illustrative and are not intended to limit the scope of claims. Techniques described in the scope of claims include various modifications and changes made to the specific examples illustrated above.

It is to be understood that the technical elements described in the present specification and the drawings exhibit technical usefulness solely or in various combinations thereof, and shall not be limited to the combinations described in the claims at the time of filing. Furthermore, the techniques illustrated in the present specification and the drawings are to achieve a plurality of objectives at the same time, whereby technical usefulness is exhibited by attaining any one of such objectives.

1. A semiconductor device comprising:
a semiconductor substrate that comprises:
an n type drift layer,
a p type body layer on an upper surface side of the drift layer, and
a high impurity n layer on a lower surface side of the drift layer, the high impurity n layer including hydrogen ion donors as a dopant, and having a higher density of n type impurities than the drift layer, wherein
a lifetime control region including crystal defects as a lifetime killer is formed in the high impurity n layer and a part of the drift layer,
a donor peak position, at which a hydrogen ion donor density is highest in the high impurity n layer in a depth direction of the semiconductor substrate, is adjacent or identical to a defect peak position, at which a crystal defect density is highest in the lifetime control region in the depth direction of the semiconductor substrate, and
the crystal defect density in the defect peak position of the lifetime control region is 1×10¹² atoms/cm³ or more.

2. The semiconductor device according to claim 1, wherein a width of the high impurity n layer in the depth direction of the semiconductor substrate is 2 μm or more and 70 μm or less.

3. The semiconductor device according to claim 1, wherein
the crystal defects of the lifetime control region are formed by irradiating hydrogen ions to the semiconductor substrate at an acceleration energy of 2 MeV or more, and
the hydrogen ion donors in the high impurity n layer are formed by converting the hydrogen ions irradiated in forming the crystal defect into the hydrogen ion donors.

4. A method of manufacturing a semiconductor device that comprises a semiconductor substrate that includes an n type drift layer, a p type body layer on an upper surface side of the drift layer, and a high impurity n layer on a lower surface side of the drift layer, the high impurity n layer including hydrogen ion donors as a dopant, and having a higher density of n type impurities than the drift layer,
the method comprising:
preparing a semiconductor wafer comprising the drift layer;
irradiating hydrogen ions to the drift layer of the semiconductor wafer at an acceleration energy of 2 MeV or more to form crystal defects; and
activating the hydrogen ions irradiated to form the high impurity n layer, and leaving at least a part of the crystal defects formed by the irradiating in the semiconductor wafer.

5. The method for manufacturing a semiconductor device according to claim 4, wherein
the irradiating irradiates the hydrogen ions to the drift layer of the semiconductor wafer at the acceleration energy of 2 MeV or more and 20 MeV or less.

6. The method for manufacturing a semiconductor device according to claim 4, wherein
the activating includes annealing the semiconductor wafer at a wafer temperature of 200 degrees Celsius or more and 500 degrees Celsius or less.

7. The method for manufacturing a semiconductor device according to claim 4, wherein
the irradiating irradiates the hydrogen ions from the lower surface side of the drift layer of the semiconductor wafer.

8. The method for manufacturing a semiconductor device according to any of claim 4, wherein
the irradiating irradiates the hydrogen ions from the an upper surface side of the drift layer of the semiconductor wafer.
